(19) United States
(12) Patent Application Publication
(10) Pub. No.: US 2008/0084658 A1
(43) Pub. Date: Apr. 10, 2008

(54) CASING ASSEMBLY FOR DISPLAY DEVICE AND DISPLAY DEVICE

(75) Inventors: Fumitoshi Matsuda, Kawasaki-shi (JP); Masanori Nouchi, Yokohama (JP)

Correspondence Address: FISH & RICHARDSON PC, P.O. BOX 1022, MINNEAPOLIS, MN, 55440-1022, US

(73) Assignee: Info Vision Optoelectronics Holdings Limited

(21) Appl. No.: 11/863,933

(22) Filed: Sep. 28, 2007

(30) Foreign Application Priority Data
Oct. 4, 2006 (JP) 2006-273424

(51) Int. Cl. H05K 5/02

(52) U.S. Cl. 361/681

(57) ABSTRACT

Disclosed herein is a casing assembly for a display device. The casing assembly includes a rear casing and a front casing. The rear casing includes a middle part with an H-shaped section, the H-shaped part is provided with an upward recess for receiving a display unit and a downward recess for receiving a circuit module. The front casing is provided with an opening to expose a display panel of the display unit. The front casing and the rear casing are connected together with plug-in connecting means. The casing assembly of the present invention makes it possible to cut down the number of components of the display device as well as the steps of the assembly process. Also disclosed herein is a display device which is provided with the casing assembly of the present invention.

### CROSS-REFERENCES TO RELATED APPLICATIONS

This application claims the benefit of Japanese Patent Application No. 2006-273424 filed on Oct. 4, 2006.

### FIELD OF THE INVENTION

The present invention relates to the field of a display device, particularly to a casing assembly used for a liquid crystal display (LCD) device and an LCD device.

### BACKGROUND OF THE INVENTION

In recent years, LCD devices are commonly used as display terminals for televisions in addition to computers. There is an increasing demand for reducing the manufacture cost of these devices.

A prior LCD device comprises a front casing, hinges for securing an LCD module, a power circuit, an adapter/interface circuit, a rear frame for holding the power circuit and a rear casing. All of these members are assembled together with screws or other connection elements by a complicated process. This is disclosed in the Japanese Registered Utility Model Publication No. 3108915. A detailed description will be given hereinafter with reference to the accompanying drawings.

FIG. 1 is a perspective view of an LCD device. FIG. 2 is a sectional view of the display device composed by a prior casing assembly, taken along a sectional line Y-Y in FIG. 1.

In FIG. 2, reference numeral 101 is used to denote a front casing, 102 to a rear casing, 203 to an LCD module, 104 to a front bezel, 105 to screws, 106 to hinges, 208 to a power circuit, 110 to a rear frame for holding members such as the power circuit, 111 to a rear bezel, 211 to an adapter/interface circuit, 251 to a back light, 252 to an optical film, 253 to a polarizer, and 254 to glass substrates for holding liquid crystal therebetween.

According to a conventional assembling method, a back light frame 255, the back light 251 and the optical film 252 are all arranged on the rear bezel 111. The LCD panel consisting of the polarizer 253 and the glass substrates 254 for holding liquid crystal therebetween is secured by the hinge 106 and the front bezel 104 with screws. The rear frame 110, on which the power circuit 208 and the adapter/interface circuit 211 are arranged, is fixed to the front casing 101 with screws. Finally, the rear casing 102 is mounted and closed from the rear side. This process is considerably complicated.

However, if efforts are concentrated on the shapes of the front casing and the rear casing to form a casing assembly for the LCD device, without using screws or hinges to assemble the LCD module and the interface circuit or the power circuit together, the number of components of the LCD device as well as the steps of the assembly process may be cut down. Therefore, the manufacture cost of the LCD device can be reduced.

### SUMMARY OF THE INVENTION

Thus, the object of the present invention is to provide a casing assembly for a display device and an LCD device with such a casing assembly. The shape of the front casing and the rear casing is so improved that the casing assembly for the LCD device has a configuration which enables the LCD module, the interface circuit and the power circuit to be assembled without using hinges or screws, and the manufacture cost is reduced by a cut down of the number of components of the LCD device as well as the steps of the assembly process.

In one aspect of the present invention, there is provided a casing assembly for a display device, comprising: a rear casing including a middle part with an H-shaped section, the H-shaped part being provided with an upward recess for receiving a display unit and a downward recess for receiving a circuit module; and a front casing provided with an opening to expose a display panel of the display unit; wherein the front casing and the rear casing are connected together with connecting means.

In another aspect of the present invention, there is further providing a display device with the casing assembly as mentioned above.

With the casing assemble for the display device according to the present invention, by improving the configuration of the front casing and the rear casing, the display unit and peripheral circuits may be arranged in a more favorable way. Meanwhile, no bezels, hinges, or screws are needed during the assembly process of the LCD module, power circuits and adapters/interface circuits. Therefore, it is possible to cut down the number of components of the display device as well as the steps of the assembly process, thus to facilitate installation and disassembly as well as maintenance, and to reduce the manufacture cost.

### BRIEF DESCRIPTION OF THE DRAWINGS

FIG. 1 is a perspective view of an LCD device;

FIG. 2 is a sectional view of the display device composed by a prior casing assembly, taken along a sectional line Y-Y in FIG. 1; and

FIG. 3 illustrates a construction of a casing assembly for a display device according to an embodiment of the present invention, showing a sectional view of the display device provided with the casing assembly according to the present invention, taken along the sectional line Y-Y in FIG. 1.

### DETAILED DESCRIPTION OF THE INVENTION

Hereinafter, an embodiment of the present invention will be described in detail with reference to the accompany drawings.

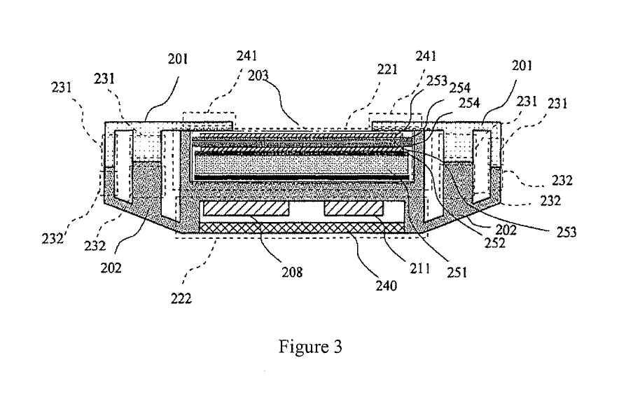

FIG. 3 illustrates a construction of a casing assembly for a display device according to an embodiment of the present invention, showing a section view of the display device provided with the casing assembly according to the present invention, taken along the section line Y-Y in FIG. 1.

In FIG. 3, reference numeral 201 is used to denote a front casing, 202 to a rear casing, 203 to an LCD module, 208 to a power circuit, 221 to an upward recess of the rear casing, 222 to a downward recess of the rear casing, 211 to an adapter/interface circuit, 240 to a cover for the downward recess of the rear casing, 251 to a back light, 252 to an optical film, 253 to a polarizer, and 254 to glass substrates for holding liquid crystal therebetween.

The casing assembly for the LCD device according to the present invention is mainly constituted by the front casing 201 and the rear casing 202, with the front casing 201 and the rear casing 202 being connected together with plug-in connection means. Specifically, the front casing 201 and the rear casing 202 are connected/integrated with each other via connection means provided on two support legs. These two support legs are a support leg 232 of the rear casing and a support leg 231 of the front casing opposite to the support leg 232 of the rear casing.

At first, the configuration of the rear casing 202 will be described with reference to FIG. 3.

As shown in FIG. 3, the rear casing 202 is provided with one recess at the view side of the LCD device and another recess at the back side respectively in a manner of its middle part having an H-shaped section, with bottoms of the two recesses arranged back-to-back. The recess at the view side is the upward recess 221, while the recess at the back side is the downward recess 222, as shown in FIG. 3.

Components of the LCD module may be sequentially laid into the upward recess 221 of the front casing of the casing assembly. These LCD module components include the back light 251, the optical film 252, the polarizer 253 and the glass substrates 254 for holding liquid crystal therebetween. According to the present invention, these LCD module components are so configured that they may be sequentially laid into the box-like upward recess 221. Therefore, the LCD module may be installed and fixed without a further need for connection elements such as screws.

In this context, the wording “upward” in “upward recess 221” means that during a laid-up process of the LCD module components into the upward recess 221, if the upward recess 221 of the rear casing 202 is oriented toward an “up” direction, the laid-up process may be carried out easily.

The rear casing is provided with the downward recess 222 for receiving the power circuit 208 and the adapter/interface circuit 211 therein. Therefore, the LCD module 203 is arranged at the view side of the H-shaped configuration of the rear casing 202, while the power circuit 208 and the adapter/interface circuit 211 are arranged at the back side of the H-shaped configuration of the rear casing 202, thus simplifying the assembly process and reducing the number of connection elements.

Furthermore, by arranging the power circuit 208 and the adapter/interface circuit 211 within the downward recess 222, it is possible to carry out a detailed examination without removing the whole rear casing 102, if certain errors occur in the LCD device and the power circuit 208 or the adapter/interface circuit 211 needs to be checked. Comparing with a conventional examination process which requires removing the whole rear casing 102, repair/maintenance of the display device according to the present invention is greatly facilitated.

Support legs 232 are provided at the periphery of the rear casing 202 for connecting to the front casing 201. The support legs 232 are further provided with connection means for connecting with the front casing 201.

Additionally, as an alternative, the cover 240 is provided for the recess at the back side of the rear casing 202, i.e. the downward recess 222. With this cover 240, it is possible to reduce dusts settling on the power circuit 208 and the adapter/interface circuit 211 in the downward recess 222.

Next, the front casing 201 will be described with reference to FIG. 3.

The front cover 201 is provided with an opening such that the screen of the LCD module 203 arranged in the upward recess 221 of the rear casing 202 may be exposed, and that the liquid crystal screen may be visible to a user of the LCD device. The outer periphery of the LCD module 203 is covered by a rectangular frame 241 surrounding images. No bezels are needed, since this rectangular frame 241 will serve as a conventional bezel.

Support legs 231 are provided at the periphery of the front casing 201 opposite to the support legs 232 at the periphery of the rear casing 202. Also, the support legs 231 are further provided with connection means for connecting with the rear casing 202. Furthermore, since such connection means are known to a person skilled in the art, a description thereof will be omitted.

With the casing assemble for the display device according to the present invention, by improving the configuration of the front casing and the rear casing, the display unit and peripheral circuits may be arranged in a more favorable way. Meanwhile, no bezels, hinges, or screws are needed during the assembly process of the LCD module, power circuits and adapters/interface circuits. Therefore, it is possible to cut down the number of components of the display device as well as the steps of the assembly process, thus to facilitate installation and disassembly as well as maintenance, and to reduce the manufacture cost.

By the way, since the casing assembly for the display device according to the present invention may be made of known material by known method, thereby a description thereof is omitted.

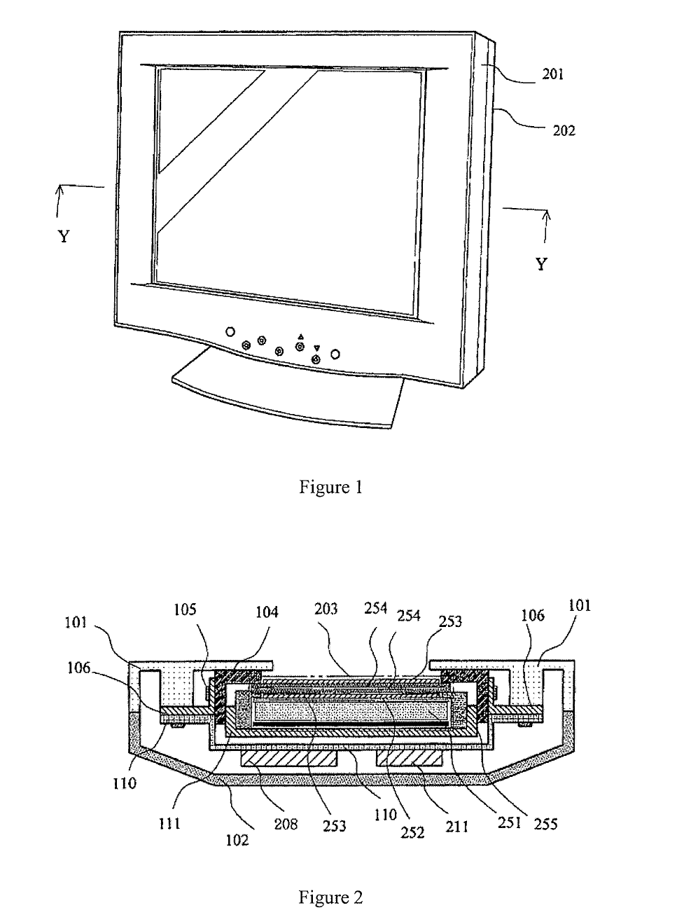

Furthermore, blank portions in FIG. 2 and FIG. 3 may be empty spaces.

The embodiment described above is merely used to explain the principle of the invention. It can be appreciated that the present invention is not limited thereto. For those skilled in the art, various variations and modifications which are made without departing from the spirit and the scope of the invention shall fall within the scope of the invention.

What is claimed is:

1. A casing assembly for a display device, said casing assembly comprising:
a rear casing (202) including a middle part with an H-shaped section, the H-shaped part being provided with an upward recess (221) for receiving a display unit and a downward recess (222) for receiving a circuit module; and
a front casing (201) provided with an opening to expose a display panel of the display unit; wherein
the front casing (201) and the rear casing (202) are connected together with connecting means.

2. The casing assembly for a display device according to claim 1, wherein the connecting means is a plug-in connecting means.

3. The casing assembly for a display device according to claim 1, wherein
support legs (232) of the rear casing are provided at the periphery of the rear casing (202) for connecting to the front casing (201), and
support legs (231) of the front casing are provided at the periphery of the front casing (201), the support legs (231) of the front casing correspond to the support legs (232) of the rear casing.

4. The casing assembly for a display device according to claim 1, wherein a frame (241) is provided at the opening of the front casing (201) for holding the display unit.

5. The casing assembly for a display device according to claim 1, wherein the display unit is an LCD module.

6. The casing assembly for a display device according to claim 1, wherein the circuit module comprises at least one of the following: a power circuit module, a drive circuit module and an adapter/interface circuit module.

7. The casing assembly for a display device according to claim 1, wherein a cover (240) is provided at an opening of the downward recess (222) of the rear casing (202) of the casing assembly.

8. A display device, said display device being provided with a casing assembly for a display device said casing assembly comprising:
a rear casing (202) including a middle part with an H-shaped section, the H-shaped part being provided with an upward recess (221) for receiving a display unit and a downward recess (222) for receiving a circuit module; and
a front casing (201) provided with an opening to expose a display panel of the display unit; wherein
the front casing (201) and the rear casing (202) are connected together with connecting means.

9. The display device according to claim 8, wherein the connecting means is a plug-in connecting means.

10. The display device according to claim 8, wherein
support legs (232) of the rear casing are provided at the periphery of the rear casing (202) for connecting to the front casing (201), and
support legs (231) of the front casing are provided at the periphery of the front casing (201), the support legs (231) of the front casing correspond to the support legs (232) of the rear casing.

11. The display device according to claim 8, wherein a frame (241) is provided at the opening of the front casing (201) for holding the display unit.

12. The display device according to claim 8, wherein the display unit is an LCD module.

13. The display device according to claim 8, wherein the circuit module comprises at least one of the following: a power circuit module, a drive circuit module and an adapter/interface circuit module.

14. The display device according to claim 8, wherein a cover (240) is provided at an opening of the downward recess (222) of the rear casing (202) of the casing assembly.
